(19) United States
(12) Patent Application Publication
(10) Pub. No.: US 2026/0328973 A1
(43) Pub. Date: Oct. 22, 2026

(54) OPTICAL SENSOR

(71) Applicant: VisEra Technologies Company Limited, Hsin-Chu City (TW)

(72) Inventors: Yi-Hsin TAI, Hsin-Chu City (TW); Hsin-Yi HSIEH, Hsin-Chu City (TW); Po-Han FU, Hsin-Chu City (TW)

(21) Appl. No.: 19/181,719

(22) Filed: Apr. 17, 2025

(51) Int. Cl. G02B 5/00; G02B 1/00; H10F 39/00; H10F 39/10; H10F 39/15; H10F 77/40

(52) U.S. Cl. CPC G02B 5/008; G02B 1/002; H10F 39/107; H10F 39/15; H10F 39/8063; H10F 77/413

(57) ABSTRACT

An optical sensor includes a surface plasmon resonance chip; a sensing medium disposed on an upper surface of the surface plasmon resonance chip; and a metasurface disposed on a lower surface of the surface plasmon resonance chip opposite the sensing medium. The optical sensor further includes a detecting element located below the metasurface. The surface plasmon resonance chip receives an incident light in a normal direction and generates a spectrum. The metasurface separates the spectrum into a first optical signal and a second optical signal, and projects the first optical signal and the second optical signal respectively onto a first area and a second area of the detecting element. The first area and the second area occupy different numbers of pixels of the detecting element.

### BACKGROUND

### Technical Field

The present disclosure relates to an optical sensor, and in particular it relates to the combination of the surface plasmon resonance (SPR) chip and the metasurface of an optical sensor.

### Description of the Related Art

Surface plasmon resonance (SPR) chips generate optical signals that are responsive to the various optical properties of multiple analytes (such as biomolecular samples). The analytes are generally planted on the surface of the surface plasmon resonance chips. Plasmons are eigenmodes of collective density oscillations of quasi-free electrons or an electronic gas in metals and other materials under optical excitation. Surface plasmons can be generated by coupling photons and electrons at or near a surface of an electrically conductive material as surface plasmon polaritons (SPP). In addition, surface plasmons can be excited or generated as localized surface plasmon resonance (LSPR) for nanometer-sized metallic structures.

Some surface plasmon resonance chips can use propagating surface plasmon polariton in sensing the refractive index change surrounding the metallic surface or nanostructure. One such chip is the surface plasmon polariton chip in the Kretschmann configuration which uses a high refractive index prism for evanescent coupling under a large incident angle to excite the liquid-metallic surface plasmon polariton wave on the liquid metal interface. Another is in the grating configuration (both reflection and transmission), which uses a grating wavevector matching condition to excite propagating surface plasmon polaritons on the interface of liquid and metallic grating. In these and other surface plasmon polariton sensing devices, the excited electric field is distributed on an extended surface area, so no concentrated electric field exists.

Although existing surface plasmon resonance chips have been adequate for their intended purposes, they have not been entirely satisfactory in all respects. Therefore, an innovative design is required to enhance the reception of the optical signals.

### SUMMARY

In an embodiment, an optical sensor includes a surface plasmon resonance chip; a sensing medium disposed on an upper surface of the surface plasmon resonance chip; a metasurface disposed on a lower surface of the surface plasmon resonance chip opposite the sensing medium; and a detecting element located below the metasurface. The surface plasmon resonance chip receives an incident light in a normal direction and generates a spectrum. The metasurface separates the spectrum into a first optical signal and a second optical signal, and projects the first optical signal and the second optical signal respectively onto a first area and a second area of the detecting element. The first area and the second area occupy different numbers of pixels of the detecting element.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a perspective view of an optical sensor, according to some embodiments of the present disclosure.

FIG. 2 is a cross-sectional view of the optical sensor, according to some embodiments of the present disclosure.

FIG. 3 is a top view of a metasurface of the optical sensor, according to some embodiments of the present disclosure.

FIG. 4 is a top view of the metasurface of the optical sensor, according to some embodiments of the present disclosure.

FIG. 5 is a top view of a detecting element of the optical sensor, according to some embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean±20% of the stated value, more typically ±10% of the stated value, more typically ±5% of the stated value, more typically ±3% of the stated value, more typically ±2% of the stated value, more typically ±1% of the stated value and even more typically ±0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

In contemporary industry, surface plasmon resonance (SPR) chips may be utilized to study a variety of analytes (for example, biomolecular samples). The characteristics of the analytes may be converted into recognizable signals (such as optical signals) by the surface plasmon resonance chips. The light change, the color variation, or the intensity shift of the optical signals may all be measured to detect and to determine the characteristics of the analytes. Conventionally, the optical signals excited from the surface plasmon resonance chips may be transmitted through filters, so the corresponding pixels of the underlying detecting element may receive pure signals, respectively. The filters may allow the desired optical signals to transmit, and may absorb the unwanted optical signals. Even though the conventional filters may ensure that the desired optical signals are to be received by the corresponding pixels, the other optical signals being absorbed may still represent a portion of the optical energy loss. When the pixels acquire only a fraction amount of the entire optical signals, the detection of the analytes may result in lower accuracy and lower signal-to-noise (S/N) ratio.

The present disclosure integrates a metasurface with the surface plasmon resonance chip to replace the conventional filters. The metasurface includes nanostructures (such as nanoposts or pillars) that generate a phase library, which provides the necessary phase difference for different wave bands (or colors) of the optical signals. When the nanostructures are arranged across the metasurface, optical signals in different wave bands may be separated, which can serve as a bandpass filter. Through designing the dimensions and the pitches of the nanostructures using an algorithm, the different optical signals may be transmitted toward the designated areas, respectively. Therefore, the present disclosure may allow the optical signals to be detected more accurately, and the signal-to-noise ratio may be improved.

Since the pixel size has been continually shrinking, the implementation of the filters has become disadvantageous. Since the scaling of the filters is very limited, it is very challenging for the filters to accommodate the shrinking pixel size. Moreover, the configuration of the filters may include multiple layers, which may adversely increase the warpage of the overall structure. The inventor has discovered that the implementation of the metasurface may serve as a promising candidate, since the metasurface may be easily designed to conform to the dimension of the pixels. Furthermore, the configuration of the metasurface does not need to be affected by the arrangement of the pixels. As a result, the surface plasmon resonance chips integrated with the metasurface can be manufactured into much smaller dimension with more superior efficiency. Furthermore, the optical sensor of the present disclosure may even be applicable in the global enzyme-linked immunosorbent assay (ELISA) market.

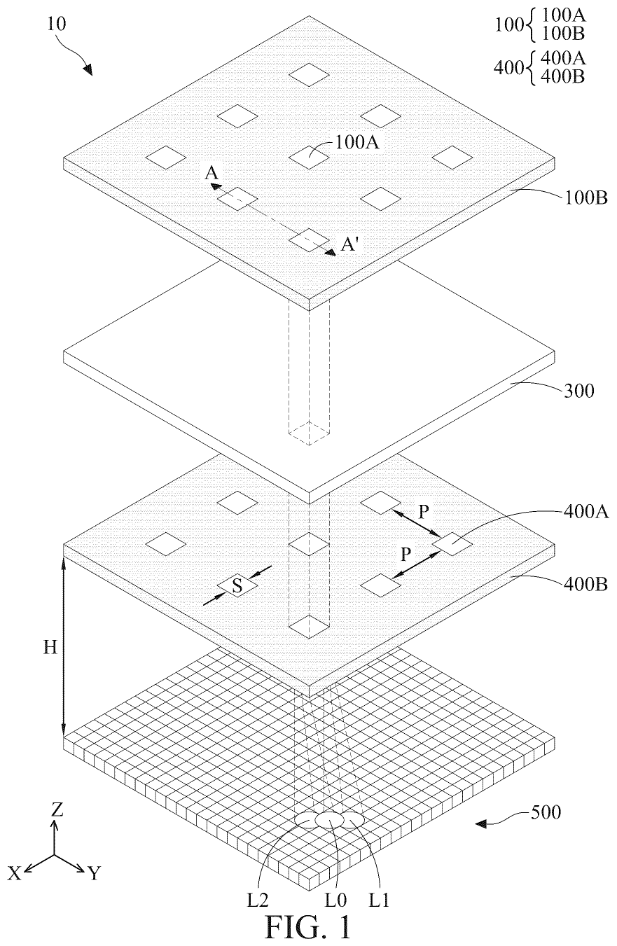

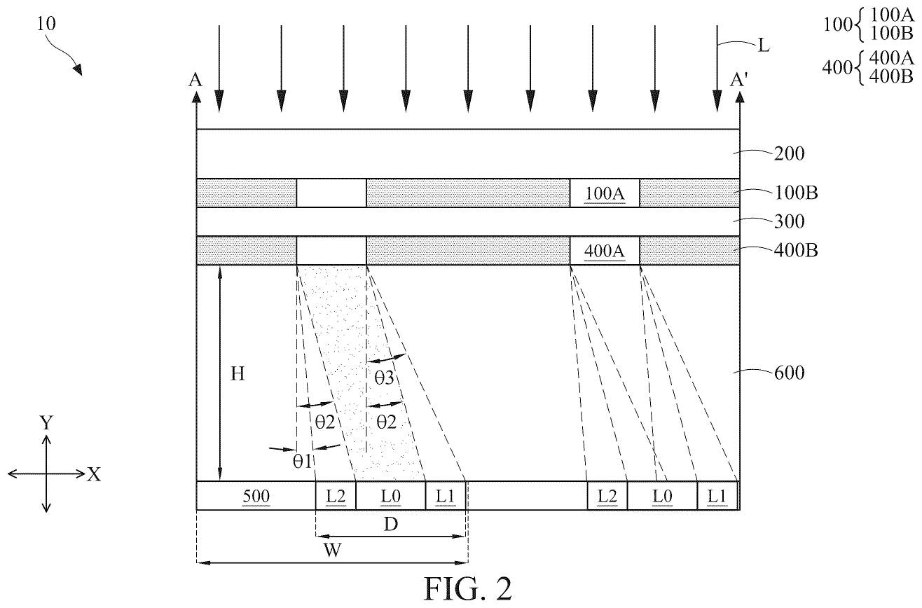

FIG. 1 is a perspective view of an optical sensor 10, according to some embodiments of the present disclosure. FIG. 2 is a cross-sectional view of the optical sensor 10, according to some embodiments of the present disclosure. It should be noted that FIG. 2 is the cross-sectional view obtained from a line A-A′ of FIG. 1. In some embodiments, optical sensors may contain millions of pixels in reality. For the sake of brevity, FIG. 1 and FIG. 2 only display a portion of an actual optical sensor. Please note that, the features of FIG. 1 are vertically spaced apart, and some features are omitted, for illustrative purpose only.

According to some embodiments of the present disclosure, the optical sensor 10 may include a surface plasmon resonance chip 100, a sensing medium 200, a polarizer 300, a metasurface 400, a detecting element 500, and a dielectric structure 600. In some embodiments, the surface plasmon resonance chip 100 may include a light transmitting region 100A and a light blocking region 100B. The metasurface 400 may include a light transmitting region 400A and a light blocking region 400B. It is worth noting that the light transmitting region 100A of the surface plasmon resonance chip 100 may correspond to the light transmitting region 400A of the metasurface 400. The light transmitting region 100A and the light transmitting region 400A may both function as a collimating structure for an incident light L to propagate. Moreover, the light blocking region 100B of the surface plasmon resonance chip 100 and the light blocking region 400B of the metasurface 400 may each include a light blocking material. Although the light blocking material may be present in both the light blocking region 100B and the light blocking region 400B, the present disclosure is not limited thereto. For example, the light blocking material may be present only in the surface plasmon resonance chip 100, or only in the metasurface 400, as long as the propagation of the incident light L may be properly blocked.

Referring to FIGS. 1 and 2, the surface plasmon resonance chip 100 is provided. In the embodiments where the surface plasmon resonance chip 100 is utilized to study a biomolecular sample, antibodies may first be planted on the surface of the surface plasmon resonance chip 100. In the presence of the antibodies, the refractive index at the surface of the surface plasmon resonance chip 100 may increase, thus the feature spectrum of the surface plasmon resonance chip 100 may be shifted to a first position. Next, the surface plasmon resonance chip 100 with the planted antibodies may be submerged into a solution where antigens are introduced. The antigens with the specificity may be linked with the antibodies on the surface plasmon resonance chip 100. The antigens with non-specificity may not be linked with the antibodies on the surface plasmon resonance chip 100, and may simply be carried away by the solution.

It should be appreciated that the presence of the antigens may allow the refractive index at the surface of the surface plasmon resonance chip 100 to increase again, and the feature spectrum of the surface plasmon resonance chip 100 may be shifted further to a second position. When the antigens have non-specificity and thus is not linked with the antibodies, the feature spectrum of the surface plasmon resonance chip 100 may be shifted from the second position back to the first position. However, when the antigens have specificity and thus is linked with the antibodies, the feature spectrum of the surface plasmon resonance chip 100 may be slightly shifted from the second position to a third position that is between the first position and the second position.

The refractive index is a characteristic of a substance that changes the speed of light, and it is a value obtained by dividing the speed of light in vacuum by the speed of light in the substance. When light travels between two different materials at an angle, its refractive index determines the angle of light transmission (refraction).

According to some embodiments of the present disclosure, when the incident light L is irradiated onto the surface plasmon resonance chip 100, the resulting feature spectrum of the surface plasmon resonance chip 100 at the second position implies the antigens had non-specificity and thus is not linked with the antibodies, while the resulting feature spectrum of the surface plasmon resonance chip 100 at the third position implies the antigens had specificity and thus is linked with the antibodies. The antibodies may function as the detection target, while the antigens may serve as the samples to be detected. In such embodiments, the surface plasmon resonance chip 100 may serve as a ligand-functionalized element. In other words, the resulting spectrum shift or intensity change may be analyzed to obtain the information of the biomolecular sample. The mechanism of the surface plasmon resonance chip 100 does not require the modification of additional fluorescent signal or additional circuit design. Therefore, the mechanism of the surface plasmon resonance chip 100 is a non-labelling assay.

It should be appreciated that the spectrum shift of the surface plasmon resonance chip 100 shown in the intensity to wavelength plot may appear to be a peak form or a dip form. The transmitted optical signal measured at the lower surface of the chip 100 may produce a spectrum characterized by a peak. Similarly, the reflected signal measured at the upper surface of the surface plasmon resonance chip 100 may produce a spectrum characterized by a dip. The peak and the dip are equivalent with each other, and may both be analyzed to determine the characteristics of the biomolecular sample on the surface of the surface plasmon resonance chip 100. When the refractive index at the surface of the surface plasmon resonance chip 100 increases, the peak or the dip may be shifted toward longer wavelength. Since the peak or the dip is shifted toward the infrared band, such behavior may also be known as a “redshift”. In contrast, when the refractive index at the surface of the surface plasmon resonance chip 100 decreases, the peak or the dip may be shifted toward shorter wavelength. Since the peak or the dip is shifted toward the ultraviolet band, such behavior may also be known as a “blueshift”.

As mentioned previously, the surface plasmon resonance chip 100 may include the light transmitting region 100A and the light blocking region 100B. The light blocking material may constitute the light blocking region 100B of the surface plasmon resonance chip 100, and may define the light transmitting region 100A of the surface plasmon resonance chip 100. According to some embodiments of the present disclosure, the light blocking material may prevent the incident light L from transmitting through areas outside the light transmitting region 100A and reaching the detecting element 500. The light transmitting region 100A may transform the incident light L into multiple collimated light beams that are propagated onto the underlying metasurface 400. In other embodiments, as long as the metasurface 400 includes the light blocking material, the surface plasmon resonance chip 100 may be free of the light blocking material. Without the light blocking material, the entire surface of the surface plasmon resonance chip 100 may be light-transmissive.

In some embodiments, the surface plasmon resonance chip 100 may include a substrate, a conductive layer, and a dielectric layer (not shown for simplicity) that are sequentially formed. Materials of the substrate may include glass, quartz, polymer, the like, or a combination thereof. Materials of the conductive layer may include gold (Au), silver (Ag), aluminum (Al), the like, or a combination thereof. Materials of the dielectric layer may include silicon dioxide (SiO₂), titanium dioxide (TiO₂), polymer, the like, or a combination thereof. In some embodiments, the substrate may include a perforated structure that is periodically arranged. The overlying conductive layer and dielectric layer may both adapt to the profile of the substrate.

Still referring to FIGS. 1 and 2, the sensing medium 200 may be disposed on the upper surface of the surface plasmon resonance chip 100. In some embodiments, the sensing medium 200 may be where the analytes on the surface plasmon resonance chip 100 are located. When the incident light L reaches the surface plasmon resonance chip 100, a portion of the optical energy may be excited, and an optical field may be generated. The optical field may have the highest peak close to the surface of the surface plasmon resonance chip 100, and may be exponentially decayed in the vertical direction away from the surface of the surface plasmon resonance chip 100 (into the sensing medium 200). In other words, the sensing capability of the surface plasmon resonance chip 100 may be gradually weakened when the analytes are placed further away from the surface plasmon resonance chip 100. Therefore, the height of the sensing medium 200 may be the decay length of the optical field. The height of the sensing medium 200 may be between 200 nm and 300 nm. In some embodiments, the sensing medium 200 may be air or solution, which has the refractive index of 1.

Referring to FIGS. 1 and 2, the polarizer 300 may be disposed on the lower surface of the surface plasmon resonance chip 100 opposite the sensing medium 200. In some embodiments, the optical signals from the surface plasmon resonance chip 100 may need to be polarized for filtering. According to some embodiments of the present disclosure, the polarizer 300 may be function to polarize the output signals from the surface plasmon resonance chip 100 into a transverse magnetic (TM) polarized signal. Other than the transverse magnetic polarization, there also exists a transverse electric (TE) polarization. However, the transverse electric polarized signal cannot be generated for the surface plasmon resonance chip 100. The electric filed for the transverse magnetic polarization is parallel to the plane of incidence, while the electric field for the transverse electric polarization is perpendicular to the plane of incidence.

In the conventional design, a polarizer is required to polarize the optical signals before the optical signals are transmitted through the filter. Since the present disclosure incorporates the metasurface 400 to replace the conventional filter, the placement of the polarizer 300 may be optional. It should be appreciated that the metasurface 400 not only can separate the optical signals, but can also include the polarization function. Therefore, the polarizer 300 may be omitted under many circumstances. In other words, the disposition of the polarizer 300 is only necessary if the metasurface 400 operates without the polarization function. Even though the polarizer 300 is illustrated as being disposed between the surface plasmon resonance chip 100 and the metasurface 400, the present disclosure is not limited thereto. In other embodiments, the polarizer 300 may also be disposed between the metasurface 400 and the detecting element 500.

Still referring to FIGS. 1 and 2, the metasurface 400 may be disposed on the lower surface of the surface plasmon resonance chip 100 opposite the sensing medium 200. In some embodiments, the metasurface 400 may be in physical contact with the surface plasmon resonance chip 100 when the polarizer 300 is omitted. According to some embodiments of the present disclosure, the metasurface 400 may function as a spectrum selective layer, which may separate different optical signals from the surface plasmon resonance chip 100 using diffraction or refraction characteristics. The transmitting directions of the separated optical signals may be adjusted by their respective wavelengths according to the refractive indices and shapes of the metasurface 400. The separated signals may be delivered to the corresponding pixels on the detecting element 500 for reception.

According to a specific embodiment of the present disclosure, the feature spectrum of the surface plasmon resonance chip 100 where the antigens have not be linked with the antibodies may have a wave band at 580 nm (for example, at the second position). The metasurface 400 may allow the formation of two band channels, which includes a right band channel and a left band channel. In some embodiments, the divided band channels may be in a range between 5 nm and 40 nm from the wave band at 580 nm in opposing directions. For example, the right band channel may have a spectral range between 580 nm and 600 nm, and the left band channel may have a spectral range between 560 nm and 580 nm. In some embodiments, since the right band channel and the left band channel are extended from the feature spectrum at the wave band of 580 nm equally in opposing directions, the right band channel and the left band channel may each be overlapped equally with the feature spectrum at the wave band of 580 nm.

In some embodiments, when the antibodies planted on the surface of the light transmitting region 100A of the surface plasmon resonance chip 100 are initially exposed to the antigens having specificity, the signal monitoring may begin simultaneously. In doing so, some false signals may be generated at the early stage before most (if not all) of the antigens are linked with the antibodies. By designing, for example, a microfluidic channel in the sensing medium 200, the buffer solution and water may be continuously flowed through the light transmitting region 100A, so the antigens not linked with the antibodies may be carried away. It should be appreciated that the feature spectrum displayed by the monitored signal may be continuously shifted (either redshift or blueshift) until all the antigens not linked with the antibodies are carried away through the microfluidic channel. When the feature spectrum stops shifting (or shifting in a magnitude smaller than the monitoring system variation), the resulting feature spectrum may be considered as the genuine signal where all the antigens and all the antibodies are linked with each other.

After a period of time, the feature spectrum of the surface plasmon resonance chip 100 where the antigens have been linked with the antibodies may be settled to a new wave band (for example, at the third position spaced apart from the second position). The feature spectrum may be positioned at a wave band larger than 580 nm (redshift), or at a wave band smaller than 580 nm (blueshift). In other words, the feature spectrum may be shifted to one of the right band channel and the left band channel. Whether the feature spectrum is redshifted or blueshifted, the right band channel and the left band channel may be overlapped differently with the shifted spectrum. For example, the overlapped region between the right band channel and the feature spectrum may be larger or smaller than the overlapped region between the left band channel and the feature spectrum. Each of the overlapped region may represent the optical intensity at the respective band channel. Therefore, the difference between the optical intensity in the right band channel and the optical intensity in the left band channel may be utilized to determine the spectrum shift, which in turn determines the biomolecular characteristics of the sample and the concentration change.

In some embodiments, when the incident light L propagates through the sensing medium 200 onto the surface plasmon resonance chip 100, the optical signals from the surface plasmon resonance chip 100 allows the analytes (such as the biomolecular sample including the antigens being linked with the antibodies) in the sensing medium 200 to be detected. Since the resulting spectrum of the antigens being linked with the antibodies may span across the right band channel (from 580 nm to 600 nm) and the left band channel (from 560 nm to 580 nm), one portion of the optical intensity from the feature spectrum may be overlapped with the right band channel, and another portion of the optical intensity from the feature spectrum may be overlapped with the left band channel.

It should be appreciated that the optical intensity of the spectrum in the right band channel and the optical intensity of the spectrum in the left band channel may be considered as two optical signals of the spectrum that are spatially apart. The optical intensity of the spectrum in the right band channel and the optical intensity of the spectrum in the left band channel may then be projected respectively onto a first area L1 and a second area L2 of the detecting element 500 (to be described in more detail subsequently). By analyzing the intensity difference of the spectrum between the right band channel and the left band channel, the spectrum shift of the spectrum (from before the antigen link to after the antigen link) may then be calculated. The following equation calculates the intensity shift of the spectrum between the right band channel and the left band channel:

$$γ = \frac{{I}_{1} - {I}_{2}}{{I}_{1} + {I}_{2}} \qquad ( 1 )$$

In equation (1), I₁ is the optical intensity of the spectrum in the right band channel (from 580 nm to 600 nm) that is to be projected onto the first area L1, and I₂ is the optical intensity of the spectrum in the left band channel (from 560 nm to 580 nm) that is to be projected onto the second area L2. Moreover, γ is the normalized factor for the intensity shift.

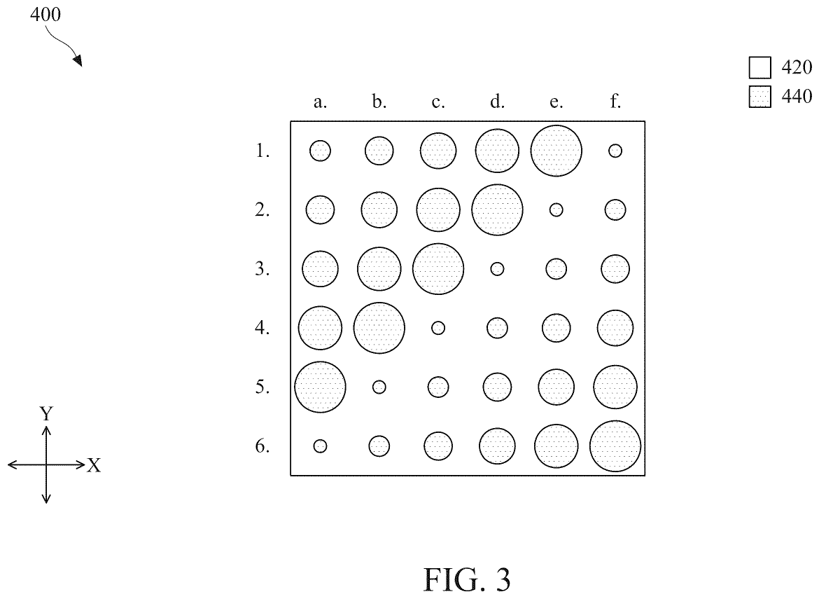

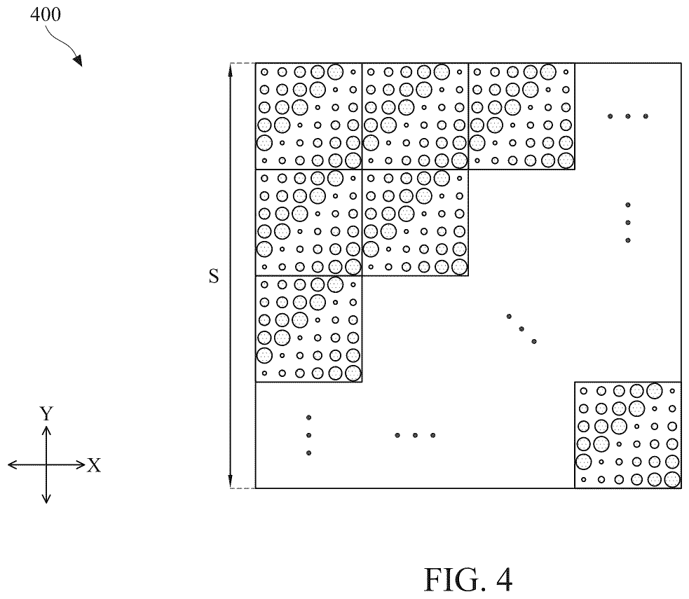

As mentioned previously, the metasurface 400 may include the light transmitting region 400A and the light blocking region 400B. The light blocking material may constitute the light blocking region 400B of the metasurface 400, and may define the light transmitting region 400A of the metasurface 400. The light transmitting region 400A may be constituted by a plurality of metalenses (to be described in more detail in reference to FIG. 4), which are laterally separated by the light blocking material. Each of the plurality of metalenses may include a plurality of unit cells (to be described in more detail in reference to FIG. 3). Each metalens may have a dimension S, and neighboring metalenses (in x-axis direction and/or in y-axis direction) may be separated by a space P. The dimension S of each metalens may be between 10 μm and 1 cm, for example, 218 μm. The space P between neighboring metalenses may be between 0 μm and 1 cm, for example, 1605 μm. In other embodiments, as long as the surface plasmon resonance chip 100 includes the light blocking material, the metasurface 400 may be free of the light blocking material. Without the light blocking material, the entire surface of the metasurface 400 may be light-transmissive.

It should be appreciated that even though the metasurface 400 may separate the output signals from the surface plasmon resonance chip 100 into different optical signals (or optical intensities) propagating toward the respective areas, it is ideal for the optical propagating paths to be in the normal direction (such as the direction of the incident light L), or as close to the normal direction as possible. Therefore, the presence of the light blocking material in at least one of the surface plasmon resonance chip 100 and the metasurface 400 is required. As mentioned previously, the incident light L may be transformed into the multiple collimated light beams. When each collimated light beam is separated by each metalens of the metasurface 400, the propagating angles of the separated optical intensities may be relatively close to the normal direction.

Referring to FIGS. 1 and 2, the detecting element 500 may be located below the metasurface 400. In some embodiments, the detecting element 500 may be vertically spaced apart from the metasurface 400, for example, by the dielectric structure 600. According to some embodiments of the present disclosure, the detecting element 500 may transduce the optical intensities of the spectrum (separated by the metasurface 400) into the corresponding voltage or current output. The detecting element 500 may be a complementary metal-oxide semiconductor (CMOS) transistor, a charged-coupled device (CCD), or any suitable optical sensing element. In some embodiments, the detecting element 500 may include an array of pixels.

According to some embodiments of the present disclosure, the first area L1 and the second area L2 may each occupy a different number of the pixels. As mentioned previously, the first area L1 and the second area L2 may correspond to the optical intensity of the spectrum in the right band channel (from 580 nm to 600 nm) and the optical intensity of the spectrum in the left band channel (from 560 nm to 580 nm), respectively. Since the spectral range of the right band channel and the spectral range of the left band channel intersect at the wave band of 580 nm, there exists an overlapped area L0 positioned between the first area L1 and the second area L2. The overlapped area L0 may represent the optical intensity of the spectrum where the optical intensity of the spectrum in the right band channel (from 580 nm to 600 nm) and the optical intensity of the spectrum in the left band channel (from 560 nm to 580 nm) overlapping with each other at the wave band of 580 nm. Since the intensity change cannot be determined from the overlapped area L0, the pixels occupied by the overlapped area L0 may also be considered as invalid pixels.

As shown in FIG. 2, the separated optical intensities of the spectrum may be propagated from the metasurface 400 onto the detecting element 500 through the dielectric structure 600 at various propagating angles. The dielectric structure 600 may have a height H. The optical intensity of the spectrum in the left band channel (from 560 nm to 580 nm) may be propagated onto the second area L2 between an angle θ1 and an angle θ2 relative to the direction of the incident light L (for example, the normal direction). The optical intensity of the spectrum in the right band channel (from 580 nm to 600 nm) may be propagated onto the first area L1 between the angle θ2 and an angle θ3 relative to the direction of the incident light L (for example, the normal direction). According to a specific embodiment of the present disclosure, the angle θ3 is larger than the angle θ2, and the angle θ2 is larger than the angle θ1.

In some embodiments, each metalens may be corresponded to a maximum dimension W on the detecting element 500, which defines the boundary where the separated optical intensities may be projected onto. As mentioned previously, it is ideal for the optical propagating paths to be as close to the normal direction as possible. The dimension W may simply be the sum of the dimension S of each metalens and the space P, and may be between 10 μm and 2 cm. Moreover, the sum of the dimension of the first area L1, the dimension of the second area L2, and the dimension of the overlapped area L0 may be a total dimension D, which is the available detection area for the separated optical signals. It is worth noting that since the optical intensity of the spectrum is propagated onto the overlapped area L0 constantly at the angle θ2, the dimension of the overlapped area L0 may simply equal to the dimension S of each metalens. The propagating path for the overlapped area L0 is highlighted (as shown in FIG. 2), for illustrative purpose only.

The following equations calculate some of the critical dimensions on the detecting element 500:

W=S+P (2)

D₁=H×(tan θ3−tan θ2) (3)

D₂=H×(tan θ2−tan θ1) (4)

D=D₁+D₂+S (5)

In equation (2), the maximum dimension W for optical projection may be the sum of the dimension S of each metalens and the space P, as stated above. In equation (3) and equation (4), D₁ and D₂ are the dimension of the first area L1 and the dimension of the second area L2, respectively. Based on the trigonometric principles, multiplying the height H of the dielectric structure 600 by the difference between the tangent of the angle θ3 and the tangent of the angle θ2 may obtain the dimension of the first area L1. Similarly, multiplying the height H of the dielectric structure 600 by the difference between the tangent of the angle θ2 and the tangent of the angle θ1 may obtain the dimension of the second area L2. In equation (5), the total dimension D may simply be obtained by adding the dimension of the first area L1, the dimension of the second area L2, and the dimension S (which equals the dimension of the overlapped area L0).

Still referring to FIGS. 1 and 2, the dielectric structure 600 may be disposed between the metasurface 400 and the detecting element 500. In some embodiments, the dielectric structure 600 may cover the detecting element 500. According to some embodiments of the present disclosure, the dielectric structure 600 may provide the necessary propagating path for the separated optical intensities of the spectrum to be projected onto their respective targets. In other words, the dielectric structure 600 may be considered as a required space, so a more superior analyzing capability of the spectrometer may be obtained. The refractive index of the dielectric structure 600 is between 1 and 1.47. Moreover, the refractive index of the dielectric structure 600 is significantly lower than that of the nanostructures 440 of the metasurface 400 (to be described in more detail in reference to FIG. 3). In some embodiments, the dielectric structure 600 may be air. According to some embodiments of the present disclosure, the height H of the dielectric structure 600 may be between 400 μm and 1 cm. It should be understood that ideally, the thickness of the dielectric structure 600 should be maintained as small as possible. The dimension of the dielectric structure 600 may determine the propagating paths of the separated optical intensities of the spectrum. Because a thinner dielectric structure 600 may allow the separated optical intensities of the spectrum to reach the respective targets more accurately. However, when the thickness of the dielectric structure 600 is set too small, the fabrication would be too challenging.

FIG. 3 is a top view of the metasurface 400 of the optical sensor 10, according to some embodiments of the present disclosure. More specifically, a single unit cell of one of the plurality of metalenses is illustrated. According to some embodiments of the present disclosure, the metasurface 400 may include a filling layer 420 and a plurality of nanostructures 440. The dimension of each unit cell may be between 0.6 μm and 10 μm, for example, 2.18 μm. For illustrative purposes, the surface plasmon resonance chip 100, the sensing medium 200, the polarizer 300, the detecting element 500, and the dielectric structure 600 are similar to those illustrated in FIG. 1 and FIG. 2, and the details are not described again herein to avoid repetition.

Referring to FIG. 3, the filling layer 420 may laterally surround the plurality of nanostructures 440. The thickness of the metasurface 400 (along the z-axis direction) may be between 0.5 μm and 3 μm, for example, 1.7 μm. In some embodiments, the filling layer 420 and the plurality of nanostructures 440 may be the same thickness. In other embodiments, the thickness of the filling layer 420 and that of the plurality of nanostructures 440 may vary, depending on the application and the design requirements.

In some embodiments, each of the plurality of nanostructures 440 may have a circular shape, a rectangular shape, a hexagonal shape, or any other symmetrical shape from a top view. The dimension of each of the plurality of nanostructures 440 from a top view may be between 10 μm and 1 cm. The pitch between neighboring nanostructures 440 (for example, the distance between the center of one nanostructure and the center of another nanostructure) may be between 200 nm and 800 nm, for example, 374 nm. According to some embodiments of the present disclosure, the refractive index of the filling layer 420 is less than the refractive index of the plurality of nanostructures 440. The refractive index of the filling layer 420 may be 1.5, which is lower than that of the nanostructures. For the designated wavelength range from 560 nm to 600 nm, the refractive index of the plurality of nanostructures 440 may be between 1.5 and 2.4, for example, 2.2. In some embodiments, the filling layer 420 may be air, which has the refractive index of 1.

It should be noted that, when the plurality of nanostructures 440 are surrounded by ambient air, the largest difference between the refractive indices may be realized to generate a significantly broader phase difference, so the optical signals of the spectrum may be more easily separated based on the band channels. When the optical signals of the spectrum in different band channels come in contact with a certain nanostructure 440, the optical signal of longer wavelength may view the nanostructure 440 differently form the optical signal of shorter wavelength, thus the phase difference is generated.

The plurality of nanostructures 440 may be made of conductive or dielectric materials, such as aluminum oxide (Al₂O₃), niobium (V) oxide (Nb₂O₅), gallium nitride (GaN), tantalum pentoxide (Ta₂O₅), titanium nitride (TiN), titanium dioxide (TiO₂), silicon nitride (SiN), silane (SiH₄), silicon oxide (SiO), the like, or a combination thereof. Materials of the filling layer 420 may include polymers or dielectric materials, such as polyethylene terephthalate (PET) resins, polycarbonate (PC) resins, polyimide (PI) resins, polymethylmethacrylates (PMMA), polystyrene resins, polyethersulfone (PES) resins, polythiophene (PT) resins, phenol novolac (PN), the like, or a combination thereof.

The metasurface 400 may be formed by patterning the plurality of nanostructures 440, followed by filling the space between the plurality of nanostructures 440 with the filling layer 420. Initially, a material layer may be formed using a suitable deposition process, such as chemical vapor deposition (CVD), high-density plasma chemical vapor deposition (HDP-CVD), plasma-enhanced chemical vapor deposition (PECVD), low-pressure chemical vapor deposition (LPCVD), flowable chemical vapor deposition (FCVD), sub-atmospheric chemical vapor deposition (SACVD), the like, or a combination thereof. Next, a hard mask layer (not shown) is coated on the material layer. In some embodiments, the hard mask layer may be a photoresist. A photolithography process is performed to pattern the hard mask layer, which may include resist coating, soft baking, exposure, post-exposure baking, development, the like, or a combination thereof. After that, an etching process (such as dry etching, wet etching, the like, or a combination thereof) is performed on the material layer by using the patterned hard mask. After the etching process, a portion of the material layer is removed, and multiple openings are formed therein. As mentioned previously, the openings will be subsequently filled with the filling layer 420.

Still referring to FIG. 3, a number of the plurality of nanostructures 440 may be constituted into a structural group. In the present embodiment, six of the plurality of nanostructures 440 may be constituted into a structural group. Although the structural group is illustrated as having six nanostructures 440, the present disclosure is not limited thereto. For example, the structural group may include any suitable number of nanostructures 440. Since the illustrated structural group includes six nanostructures 440, the illustrated unit cell may be designed with six rows and six columns. For clarity, the plurality of nanostructures 440 may be indicated by rows 1-6 (in the y-axis direction) and columns a-f (in the x-axis direction). Furthermore, the six nanostructures 440 within each structural group may be arranged in order of dimension along a row and/or along a column. For example, in column f, the six nanostructures 440 within the structural group are arranged in order of increasing dimensions from row 1 to row 6. In row 6, the six nanostructures 440 within the structural group are arranged in order of increasing dimensions from column a to column f.

It is worth noting that the nanostructures 440 in some rows or in some columns do not appear to be arranged in order of dimensions. This is only because these rows and these columns of the unit cell do not include a complete structural group. For example, in column a, the nanostructures 440 are arranged in order of increasing dimensions only from row 1 to row 5, while the nanostructure 440 of row 6 is smaller than the nanostructure 440 of row 5. However, if a plurality of unit cells were to be arranged in an n×n array from a top view, the unit cell from above or from below may supply a complete structural group. For example, in column a, the nanostructure 440 of row 6 of the unit cell above (not shown) may be joined with the nanostructures 440 from row 1 to row 5 of the present unit cell to constitute a complete structural group. Alternatively, in column a, the nanostructures 440 from row 1 to row 5 of the unit cell below (not shown) may be joined with the nanostructure 440 of row 6 of the present unit cell to constitute another complete structural group. In other words, there may not be a complete structural group in every row and in every column within the present unit cell. That is, the structural groups are not precisely aligned from column a to column f, or from row 1 to row 6 in a single unit cell.

FIG. 4 is a top view of the metasurface 400 of the optical sensor 10, according to some embodiments of the present disclosure. More specifically, one of the plurality of metalenses is illustrated. According to some embodiments of the present disclosure, each metalens may include the plurality of unit cells. As mentioned previously, each metalens may have the dimension S. For illustrative purposes, the surface plasmon resonance chip 100, the sensing medium 200, the polarizer 300, the detecting element 500, and the dielectric structure 600 are similar to those illustrated in FIG. 1 and FIG. 2, and the details are not described again herein to avoid repetition.

Referring to FIG. 4, the plurality of unit cells may be arranged in an n×n array from a top view, where n is a positive integer. In a specific embodiment of the present disclosure, the plurality of unit cells may be arranged in a 10×10 array from a top view. Although the array of unit cells is illustrated as 10×10, the present disclosure is not limited thereto. For example, each metalens may include any suitable array of the unit cells. As mentioned previously, some rows or some columns in a single unit cell do not include a complete structural group. However, when the plurality of unit cells are to be arranged into the array as illustrated, the adjacent unit cells may supply a complete structural group. If the boundaries of all the unit cells are neglected, the structural group may appear to be repeatedly arranged in cycles along every row and along every column.

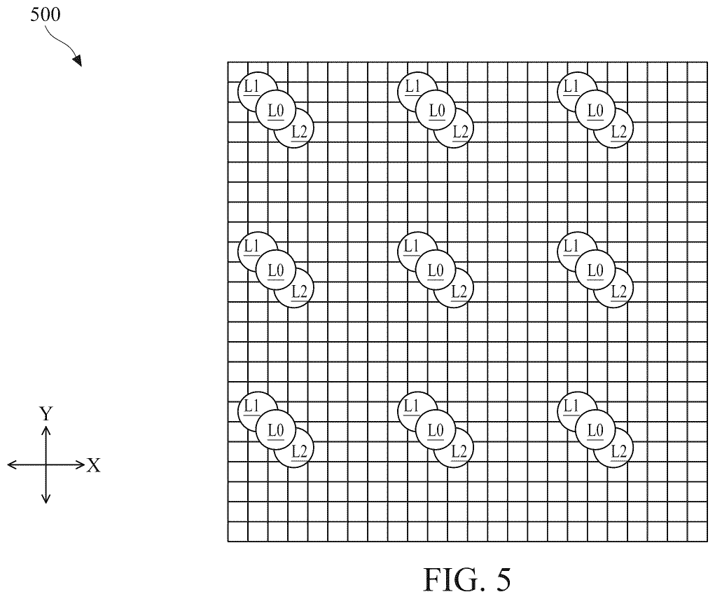

FIG. 5 is a top view of the detecting element 500 of the optical sensor 10, according to some embodiments of the present disclosure. Under each metalens, there exists the first area L1, the second area L2, and the overlapped area L0. For illustrative purposes, the surface plasmon resonance chip 100, the sensing medium 200, the polarizer 300, the metasurface 400, and the dielectric structure 600 are similar to those illustrated in FIG. 1 and FIG. 2, and the details are not described again herein to avoid repetition.

Referring to FIG. 5, the detecting element 500 may include an array of pixels, as stated above. The first area L1, the second area L2, and the overlapped area L0 may each occupy a certain number of pixels. The remainder of the surface of the detecting element 500 outside the first area L1, the second area L2, and the overlapped area L0 (for example, the area not being projected by optical intensities) may be considered as a non-sensing area. The number of pixels in the first area L1 and the number of pixels in the second area L2 may be different due to the different projected angles. As mentioned previously, it is ideal for the optical propagating paths to be as close to the normal direction as possible. Therefore, for each metalens, to achieve the maximum dimension W of the detecting element 500, it may be necessary to confine the projections of the corresponding first area L1, second area L2, and overlapped area L0 without interfering with the neighboring metalens.

The present disclosure integrates the metasurface with the surface plasmon resonance chip to replace the conventional filters. Conventionally, the optical signals excited from the surface plasmon resonance chips may be transmitted through the filters, so the respective pixels below may receive pure signals. The filters may transmit the desired optical signals, and may absorb the unwanted optical signals. Even though the desired optical signals may be received by the corresponding pixels, the other optical signals being absorbed may still represent a portion of the optical energy loss. When the pixels acquire only a fraction amount of the entire optical signals, the detection of the analytes may be less accurate. The metasurface may generate a phase library that provides the necessary phase difference for different wavelengths (or colors) of the optical signals. Optical signals in different wave bands may be separated and propagated to the corresponding pixels, respectively. It is discovered that the metasurface may be easily designed to conform to the dimension of the pixels. Therefore, the present disclosure may allow the optical signals to be detected more accurately, and the signal-to-noise ratio may be improved.

The foregoing outlines features of several embodiments so that those skilled in the art will better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the prior art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. An optical sensor, comprising:
a surface plasmon resonance chip;
a sensing medium disposed on an upper surface of the surface plasmon resonance chip;
a metasurface disposed on a lower surface of the surface plasmon resonance chip opposite the sensing medium; and
a detecting element located below the metasurface, wherein the surface plasmon resonance chip receives an incident light in a normal direction and generates a spectrum, wherein the metasurface separates the spectrum into a first optical signal and a second optical signal, and projects the first optical signal and the second optical signal respectively onto a first area and a second area of the detecting element, wherein the first area and the second area occupy different numbers of pixels of the detecting element.

2. The optical sensor of claim 1, wherein the metasurface further comprising:
a plurality of nanostructures; and
a filling layer laterally surrounding the plurality of nanostructures.

3. The optical sensor of claim 2, wherein a predetermined number of the plurality of nanostructures constitute a structural group.

4. The optical sensor of claim 3, wherein the nanostructures within the structural group are arranged in order of dimensions along a row and a column, wherein the structural group is repeatedly arranged in cycles along the row and the column.

5. The optical sensor of claim 3, wherein a light blocking material laterally separates the metasurface into a plurality of metalenses.

6. The optical sensor of claim 5, wherein the light blocking material constitutes a light blocking region of the metasurface, and the plurality of metalenses constitute a light transmitting region of the metasurface.

7. The optical sensor of claim 5, wherein each of the plurality of metalenses comprises a plurality of unit cells arranged in an n×n array from top view, wherein n is a positive integer.

8. The optical sensor of claim 7, wherein each of the plurality of unit cells comprises the predetermined number of rows and the predetermined number of columns from top view.

9. The optical sensor of claim 5, wherein each of the plurality of metalenses has a dimension, and the plurality of metalenses are separated from each other by a space.

10. The optical sensor of claim 9, wherein a sum of the dimension and the space is calculated in a following equation:
W=S+P
wherein W represents a maximum dimension for optical projections of the first optical signal and the second optical signal onto the detecting element.

11. The optical sensor of claim 2, wherein a refractive index of the filling layer is less than a refractive index of the plurality of nanostructures, wherein the filling layer is air.

12. The optical sensor of claim 1, wherein a light blocking material constitutes a light blocking region of the surface plasmon resonance chip, and defines a light transmitting region of the surface plasmon resonance chip.

13. The optical sensor of claim 1, wherein a polarizer is disposed between the surface plasmon resonance chip and the metasurface.

14. The optical sensor of claim 1, wherein a polarizer is disposed between the metasurface and the detecting element.

15. The optical sensor of claim 1, wherein the sensing medium is air or solution.

16. The optical sensor of claim 10, wherein the second optical signal is propagated onto the second area between a first angle and a second angle relative to the incident light, and the first optical signal is propagated onto the first area between the second angle and a third angle relative to the incident light, wherein the third angle is larger than the second angle, and the second angle is larger than the first angle.

17. The optical sensor of claim 16, further comprising a dielectric structure disposed between the metasurface and the detecting element, wherein the first area and the second area are defined by the first angle, the second angle, the third angle, and a height of the dielectric structure in following equations:
D₁=H×(tan θ3−tan θ2)
D₂=H×(tan θ2−tan θ1)
wherein D₁ and D₂ represent dimensions of the first area and the second area, respectively.

18. The optical sensor of claim 17, wherein an overlapped optical signal between the first optical signal and the second optical signal is propagated onto an overlapped area of the detecting element at the second angle.

19. The optical sensor of claim 18, wherein the overlapped area is positioned between the first area and the second area, wherein a dimension of the overlapped area equals to the dimension of each of the plurality of metalenses.

20. The optical sensor of claim 19, wherein a sum of the dimensions of the first area, the second area, and the overlapped area is calculated in a following equation:
D=D₁+D₂+S
wherein D represents an available detection area for the first optical signal and the second optical signal onto the detecting element.
